(19) United States
(12) Patent Application Publication
(10) Pub. No.: US 2014/0190006 A1
(43) Pub. Date: Jul. 10, 2014

(54) METHOD FOR MANUFACTURING CHARGED PARTICLE BEAM LENS

(71) Applicants: Yutaka Setomoto, Tokyo (JP); Takahisa Kato, Brookline, MA (US)

(72) Inventors: Yutaka Setomoto, Tokyo (JP); Takahisa Kato, Brookline, MA (US)

(73) Assignee: CANON KABUSHIKI KAISHA, Tokyo (JP)

(21) Appl. No.: 14/005,037

(22) PCT Filed: Mar. 14, 2012
(86) PCT No.: PCT/JP2012/001771

§ 371 Date: Mar. 17, 2014

(30) Foreign Application Priority Data
Mar. 15, 2011 (JP) 2011-056810

(51) Int. Cl. H05K 3/46

(52) U.S. Cl. CPC H05K 3/4679
USPC 29/852

(57) ABSTRACT

There is provided a method for manufacturing a charged particle beam lens having a bonded electrode obtained by bonding at least a first conductive substrate having a first through-hole and a second conductive substrate having a second through-hole. The above method includes: forming the first through-hole in the first conductive substrate; forming the second through-hole in the second conductive substrate; and bonding the first conductive substrate and the second conductive substrate so that the first through-hole and the second through-hole communicate with each other.

### TECHNICAL FIELD

The present invention relates to a charged particle beam lens used for a charged particle beam exposure apparatus and the like.

### BACKGROUND ART

A charged particle beam lens, in particular, an electron lens, can be roughly classified into an electromagnetic type lens (also called an electromagnetic lens) and an electrostatic type lens (also called an electrostatic lens). Compared to the electromagnetic type lens, the electrostatic type lens has a simple structure and can advantageously realize reduction in size and increase in integration. As an electrostatic lens used for an electron beam exposure apparatus, for example, a so-called einzel lens disclosed in PTL 1 has been generally used. Among three electrode substrates forming this einzel lens, an earth potential is generally applied to two electrode substrates located at the top and the bottom, and a negative or a positive potential is applied to the intermediate electrode substrate. A circular opening is provided in each electrode substrate, and the einzel lens generates a convergence effect to electron beams passing through the opening.

However, although the static lens is generally easily formed as compared to the electromagnetic type lens, the sensitivity of optical aberration to a manufacturing error of the shape of a lens opening portion is high. That is, a deviation from a designed value of the shape of the lens opening portion is liable to influence the optical aberration. In particular, the astigmatism to the circularity of the opening is sensitive. When the circularity is degraded, electron beams converged by the electrostatic lens will unfavorably have the astigmatism and/or another aberration with a high-order term.

PTL 1 has proposed highly accurate assembly in which in drilling processing of an electrostatic lens, in order to form a multilayer structure of at least one deflector and the like provided with apertures therein, a through-hole is formed in the multilayer structure by dry etching.

### CITATION LIST

### Patent Literature

PTL 1: U.S. Pat. No. 4,902,898

### SUMMARY OF INVENTION

### Technical Problem

However, in a related example disclosed in PTL 1, a through-hole is formed from one surface (front surface) to the other surface (rear surface) of the deflector by one dry etching operation. In this case, since an etching region extends to a certain extent also in a lateral direction as the etching progresses, a transfer accuracy of a pattern is degraded as compared to that of an etching start surface, and machining accuracy of an etching finish surface may be degraded in some cases. As a result, design accuracy of the charged particle beam lens may be degraded in some cases.

Through intensive research carried out by the present inventors in order to solve the problems described above, the present invention was finally made, and according to one aspect of the present invention, there is provided a method for manufacturing an electron beam lens having a bonded electrode obtained by bonding at least a first conductive substrate having a first through-hole and a second conductive substrate having a second through-hole. This method for manufacturing an electron beam lens comprises: forming the first through-hole in the first conductive substrate; forming the second through-hole in the second conductive substrate; and bonding the first conductive substrate and the second conductive substrate so that the first through-hole communicates with the second through-hole.

### Advantageous Effects of Invention

According to the method for manufacturing an electron beam lens of the present invention, the through-holes are independently formed in the conductive substrates, and the conductive substrates are aligned and bonded to each other to form one bonded electrode; hence, the depth of the through-hole formed at one time can be made smaller than the depth of a through-hole formed in a thick electrode. Therefore, the pattern accuracy of the through-hole of the surface of the bonded electrode is increased when the conductive substrates are bonded to each other. Although an alignment error between the through-holes is generated at the time of bonding, since this is an error generated in a uniform direction, the correction thereof can be easily performed. Therefore, although an error which can be easily corrected is generated, the ratio of an error which is difficult to be corrected can be reduced. In addition, according to the present invention, since higher accuracy is realized by combination of low accurate machining steps, reduction in cost can be obtained. Since the diameters of the throughholes can be changed between the substrates, by bonding at least one thin substrate having a highly accurate through-hole of a small diameter, a highly accurate member can be easily used at a portion at which the sensitivity of the electrode is high. In addition, by bonding a thin substrate having a large diameter and low accuracy on a surface layer of the bonded substrate, an effect of reducing influence of defects of the bonded electrode can be obtained.

### BRIEF DESCRIPTION OF DRAWINGS

FIG. 1A is a view illustrating a manufacturing step according to a first example of the present invention.

FIG. 1B is a view illustrating a manufacturing step according to the first example of the present invention.

FIG. 1C is a view illustrating a manufacturing step according to the first example of the present invention.

FIG. 2A is a view illustrating a method for avoiding a bonding failure.

FIG. 2B is a view illustrating the method for avoiding a bonding failure.

FIG. 2C is a view illustrating the method for avoiding a bonding failure.

FIG. 3A is a view illustrating a manufacturing step according to a second example of the present invention.

FIG. 3B is a view illustrating a manufacturing step according to the second example of the present invention.

FIG. 3C is a view illustrating a manufacturing step according to the second example of the present invention.

FIG. 3D is a view illustrating a manufacturing step according to the second example of the present invention.

FIG. 3E is a view illustrating a manufacturing step according to the second example of the present invention.

FIG. 4A is a view illustrating a manufacturing step according to a third example of the present invention.

FIG. 4B is a view illustrating a manufacturing step according to the third example of the present invention.

FIG. 4C is a view illustrating a manufacturing step according to the third example of the present invention.

FIG. 4D is a view illustrating a manufacturing step according to the third example of the present invention.

FIG. 4E is a view illustrating a manufacturing step according to the third example of the present invention.

FIG. 4F is a view illustrating a manufacturing step according to the third example of the present invention.

FIG. 4G is a view illustrating a manufacturing step according to the third example of the present invention.

FIG. 4H is a view illustrating a manufacturing step according to the third example of the present invention.

FIG. 4I is a view illustrating a manufacturing step according to the third example of the present invention.

FIG. 5A is a view illustrating a manufacturing step according to a fourth example of the present invention.

FIG. 5B is a view illustrating a manufacturing step according to the fourth example of the present invention.

FIG. 5C is a view illustrating a manufacturing step according to the fourth example of the present invention.

FIG. 5D is a view illustrating a manufacturing step according to the fourth example of the present invention.

FIG. 5E is a view illustrating a manufacturing step according to the fourth example of the present invention.

FIG. 5F is a view illustrating a manufacturing step according to the fourth example of the present invention.

FIG. 5G is a view illustrating a manufacturing step according to the fourth example of the present invention.

FIG. 5H is a view illustrating a manufacturing step according to the fourth example of the present invention.

FIG. 6A is a view illustrating a manufacturing step according to a fifth example of the present invention.

FIG. 6B is a view illustrating a manufacturing step according to the fifth example of the present invention.

FIG. 6C is a view illustrating a manufacturing step according to the fifth example of the present invention.

FIG. 6D is a view illustrating a manufacturing step according to the fifth example of the present invention.

FIG. 6E is a view illustrating a manufacturing step according to the fifth example of the present invention.

FIG. 6F is a view illustrating a manufacturing step according to the fifth example of the present invention.

FIG. 7A is a view illustrating a manufacturing step according to a sixth example of the present invention.

FIG. 7B is a view illustrating a manufacturing step according to the sixth example of the present invention.

FIG. 7C is a view illustrating a manufacturing step according to the sixth example of the present invention.

FIG. 7D is a view illustrating a manufacturing step according to the sixth example of the present invention.

FIG. 7E is a view illustrating a manufacturing step according to the sixth example of the present invention.

FIG. 7F is a view illustrating a manufacturing step according to the sixth example of the present invention.

### DESCRIPTION OF EMBODIMENTS

In the present invention, since through-holes are separately formed in respective conductive substrates, and the conductive substrates are aligned and boned to each other to form one bonded electrode, the depth of the through-hole formed at one time can be made small as compared to that of a through-hole formed in a thick electrode. Therefore, the pattern accuracy of the through-hole of the surface of the bonded electrode formed by bonding the conductive substrates is increased. In addition, although an alignment error between the through-holes is generated at the time of bonding, since this is an error generated in a uniform direction, the correction thereof can be easily performed. On the other hand, a machining error which is increased from a machining start side of a related through-hole toward a machining finish side thereof is influenced by the mean free path of ions in the case of dry etching and is also caused by contamination, vibration, and the like; hence, the above error is not uniformly generated, and the correction thereof is not easily performed. Accordingly, although the error is generated to a certain extent according to the present invention, the ratio of error which is difficult to be corrected is reduced, and the error which can be easily corrected is primarily generated. In addition, although the cost of related highly accurate machining is high, since machining operations with low accuracy are performed in combination to obtain high accuracy in the present invention, the cost can be reduced. Since the diameters of the through-holes can be changed between the substrates, by bonding at least one substrate having a highly accurate through-hole of a small diameter and a small thickness so as to maintain predetermined machining accuracy, a highly accurate member can be easily used at a position at which the sensitivity of the electrode is high. In addition, by bonding a thin substrate having a large diameter and low accuracy on a surface layer of the bonded substrate, an effect of reducing influence of defects of the bonded electrode can be obtained.

In a method for manufacturing a charged particle beam lens of the present invention, since the electrode is formed from at least three conductive substrates, the thickness of each substrate forming the electrode can be decreased, and the machining accuracy of each through-hole 100 can be preferably improved.

In the method for manufacturing a charged particle beam lens of the present invention, when an SOI wafer (also called an SOI substrate) is used as the substrate and also as a part of the bonded electrode, it is preferable since the thickness of the electrode can be controlled with high accuracy.

In the method for manufacturing a charged particle beam lens of the present invention, even when it is intended to form a thin conductive substrate from an SOI wafer, a process for forming the conductive substrate can be performed while the total thickness of the SOI wafer is maintained large. Accordingly, compared to the case in which the conductive substrate is formed from a thin silicon wafer, highly accurate machining having excellent handling properties can be preferably performed while bending of the substrate is suppressed.

In the method for manufacturing a charged particle beam lens of the present invention, among surfaces of a device layer 6 of the SOI wafer in which the through-hole 100 is formed, a surface (also called an etching start surface) at an etching start side of the substrate, which is opposite to a handle layer 8, can be directed to a peripheral side of the electron beam lens. Since the transfer accuracy of the pattern of the etching start surface is higher than that of an etching finish surface, which is a surface located at an etching finish side, an effect of reducing the aberration can be preferably obtained.

In the method for manufacturing a charged particle beam lens of the present invention, when a first conductive substrate 1 in which the through-hole 100 is formed and a second conductive substrate 2 in which the through-hole 100 is not yet formed are bonded to each other, it is preferable since contaminations of the substrates caused by machining can be reduced, and generation of voids in the bonding can also be suppressed.

In the method for manufacturing a charged particle beam lens of the present invention, when conductive substrates in each of which the through-hole 100 is not yet formed are bonded to each other, contaminations of the substrates caused by machining can be further reduced, and hence the effect of suppressing the generation of voids in the bonding is further increased.

In the method for manufacturing a charged particle beam lens of the present invention, when the diameter of the first through-hole is changed from that of the second through-hole, even if a projection and/or contamination is present at an end portion of one through-hole, the end portion can be avoided from being directly bonded, so that voids are not likely to be formed in the bonding.

### EXAMPLES

Hereinafter, although the present invention will be described in detail with reference to Examples, the present invention is not limited thereto at all.

### Example 1

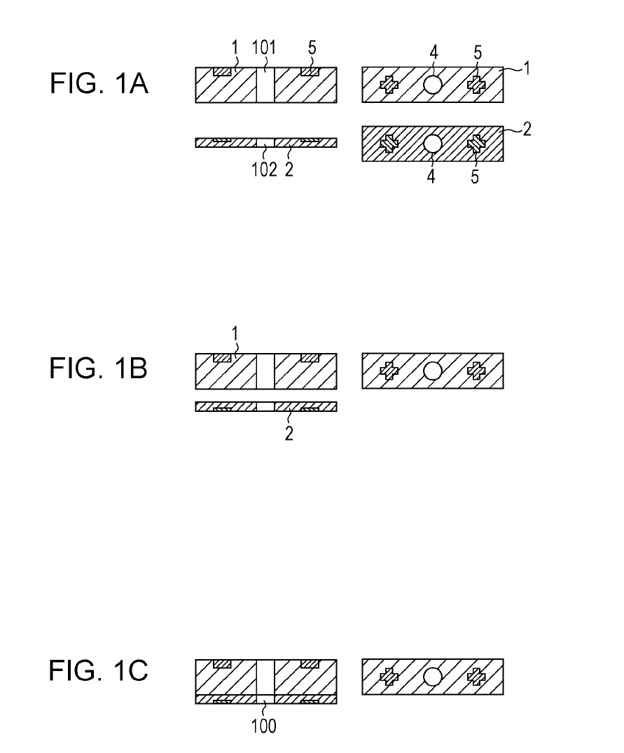

A method for manufacturing an electron beam lens of this example relates to formation of a highly accurate through-hole of an electrode forming an electron beam lens. According to the present invention, through-holes are separately formed in respective conductive substrates, and the conductive substrates are aligned and are bonded to each other to form one bonded electrode 4. Steps of the manufacturing method according to the present invention will be described with reference to FIGS. 1A to 1C. In each of FIGS. 1A to 1C, a left side view is a cross-sectional view, and a right side view is a plan view. The above one bonded electrode 4 is formed from a plurality of conductive substrates.

As shown in FIG. 1A, through a step of forming a first through-hole 101 in the first conductive substrate 1 and a step of forming a second through-hole 102 in the second conductive substrate 2, the through-holes are formed in the respective substrates.

In order to form a highly accurate through-hole, a material of each conductive substrate is processed by a semiconductor process. Therefore, the substrate is preferably a single crystal silicon wafer. In addition, the substrate preferably has conductivity since being used as an electrode. When the substrate is formed of silicon, a SiO₂ film, a SiN film, a metal film, or the like is formed on the surface of silicon as a mask material, and subsequently, patterning is performed by photolithography and etching. If a film is also formed on a rear surface of the substrate using the same material as that of the mask material, internal stresses of the films are easily counteracted to each other, and warping of the wafer can be suppressed. In addition, the film on the rear surface can also be used as a stop layer when the through-hole is formed in silicon. In particular, when a conductive material is used as the stop layer, irregularities of a side wall, which are called notches, generated when the through-hole is formed by dry etching can be suppressed. In addition, after a hole (also called a via hole) is formed from one surface side of the substrate to the middle of the substrate in a thickness direction, the thickness of the substrate is decreased by grinding or CMP from the other surface side (rear surface side) of the substrate to the bottom of the via hole. As described above, after the via holes are formed in the respective two substrates to be bonded together, in a subsequent step, the two substrates are bonded to each other so that these via holes communicate with each other, thereby forming one through-hole 100. When the surface of the substrate which is processed by grinding or CMP is to be bonded, in order to prevent bonding failure, planarization is preferably performed so that the surface roughness is decreased to approximately several nanometers or less. The through-hole of each conductive substrate is arranged at a place through which electron beams pass. The diameters of the through-holes of the conductive substrates may be the same or may be made different from each other. When the diameters of the conductive substrates are made different from each other, depending on the bonding method of the conductive substrates, it may be effective as a method for avoiding a so-called bird beak, which will be described later. When the mask material is used, by performing dry etching of silicon using ICP-RIE, the through-hole can be formed in silicon. When the thickness of the electrode is small, without performing film formation of the mask material and transfer to the mask material from a photoresist 12, ICP-RIE may be performed using the photoresist 12 to form the through-hole 100 in silicon. Concrete conditions of the dry etching may be appropriately determined according to the aspect ratio, which is a ratio of the width to the depth of each of the first and second through-holes, and required pattern machining accuracy of the through-hole 100. As one concrete example, when an aspect ratio of 3 or more is adopted as a guide, the etching can be easily performed by a Bosch process in which etching is performed by alternately changing SF₆ and C₄F₈. When the aspect ratio is lower than 3, for example, isotropic etching using SF₆ or CF₄, anisotropic etching using a mixed gas of SF₆ and CHF₃, or anisotropic etching using a mixed gas of SF₆ and O₂ may be used. By the Bosch process, a higher aspect ratio can be easily achieved. However, since irregularities called scallops are generated on the side wall of through-hole 100, when cross-sectional pattern accuracy of the through-hole 100 is taken into consideration, instead of using the Bosch process, the pattern machining accuracy of the through-hole 100 can be easily maintained by dry etching which performs no gas switching (exchange between gases). Even if the Bosch process is used, after the machining, scallops can be reduced by repeating thermal oxidation and a treatment using a hydrofluoric acid solution, and the cross-sectional pattern accuracy of the through-hole 100 can be maintained. Since the diameter of the through-hole 100 is increased corresponding to a thermally oxidized thickness, when a photomask is designed, the diameter of the through-hole pattern is decreased. In addition, when the through-hole 100 is formed, at the same time, alignment marks 5 used for alignment between the substrates are formed. In the same process as that forming the through-hole 100, holes may be formed in the silicon wafer as the alignment marks 5. The hole of the alignment mark 5 may penetrate the substrate or may be stopped in the middle thereof to form a via hole. In the case of forming a via hole, etching is once stopped when the through-hole 100 is formed, and only the portion of the alignment mark 5 may be covered with the photoresist 12. In addition, by extremely decreasing the pattern size of the alignment mark 5 from that of the through-hole 100 (for example, 1/10 or less of the diameter), the via hole may be formed by generating the different in etching rate from that of the through-hole 100. In addition, the alignment mark 5 may also be formed by patterning a thin film, such as a metal film, as a substitute. The alignment is generally performed while the alignment marks 5 of the substrates to be bonded are observed using a microscope. When visible light is used, the alignment is performed by observing the alignment marks 5 in the surfaces of the substrates from a top side and a rear side thereof. In addition, when the alignment is performed using infrared light, bonding can be performed even if the alignment marks 5 are provided at the bonding interface. In the case in which infrared light is used for the alignment, the alignment mark is formed to have a different infrared permeability or a different height as compared to that of a surrounding area so that the outline of the alignment mark 5 can be recognized by infrared light. After the through-hole 100 is formed, the first conductive substrate 1 and the second conductive substrate 2 are washed. Residues of the photoresist, the mask material, and the dry etching are removed. When the residues are present, voids are liable to be formed at the bonding interface, and hence washing is carefully and sufficiently performed. Ashing by O₂ plasma, washing by a mixed solution of sulfuric acid and a hydrogen peroxide, and washing using ozone water and a hydrofluoric acid solution are effectively performed.

FIG. 1B shows a step of aligning the first conductive substrate 1 and the second conductive substrate 2. In the alignment step, the alignment is performed so that the first through-hole 101 communicates with the second through-hole 102. When the substrates are bonded to each other, the surfaces thereof on each of which dry etching is started are preferably directed to the outside.

FIG. 1C shows a step of bonding the first conductive substrate 1 to the second conductive substrate 2.

The substrates thus aligned are bonded to each other to form the bonded electrode 4. Since the substrate processed by a method having a high pattern machining accuracy is bonded to form an outer part of the electrode, the aberration of the electron beam lens can be decreased. The reason for this is that a position of the electron beam lens closer to the periphery thereof has a higher influence on electron beams. As a bonding method, for example, fusion bonding, direct bonding, and anode bonding are preferably used. When fusion bonding is performed in the bonding step, bonding can be performed using a wafer having a SiO₂ surface formed by performing thermal oxidation on one of the conductive substrates to be bonded. When silicon is formed into SiO₂ by thermal oxidation, a projection called a bird beak or a hump is generated at the corner of the through-hole. When the bonding is performed in the state in which the projection as described above is present, a portion at which the bird beak is present is not normally bonded, and voids (defects) are generated. In order to solve this problem, when the diameter of the through-hole of the conductive substrate on which SiO₂ is formed is set smaller than that of the through-hole of the conductive substrate on which no SiO₂ is formed, generation of voids can be prevented at the time of bonding.

The steps will be more particularly described. Two double-sided polished silicon wafers each having a 4-inch diameter are prepared. A wafer having a thickness of 200 micrometers is used as the first conductive substrate 1, and a wafer having a thickness of 1,200 micrometers is used as the second conductive substrate 2. Cr films each having a thickness of 2,000 angstroms are formed on two surfaces of each of the wafers by vacuum evaporation. A photoresist is applied by spin coating on one surface of each wafer to have a thickness of 1 micrometer. By a semiconductor exposure apparatus, a pattern corresponding to the position, the number, and the size of electron beams is exposed to the photoresist. A pattern diameter of the through-hole is set to 30 micrometers for each of the first conductive substrate 1 and the second conductive substrate 2. Cross-shaped alignment marks 5 each having 10 micrometers square are formed on the same plane as that of each substrate on which the through-hole pattern is formed. The relative positions of the substrates each between the pattern for the through-hole 100 and the alignment marks 5 are set equal to each other. After the photoresist is developed, Cr functioning as an underlayer is etched by ICP-RIE using the photoresist 12 as a mask, so that silicon is exposed. As an etching gas of Cr, a mixture of Cl, O₂, and Ar is used. Next, as shown in FIG. 1A, by a silicon etching apparatus which can perform the Bosch process, silicon etching is performed in the first conductive substrate 1 and the second conductive substrate 2 by the Bosch process, so that the first through-hole 101 and the second through-hole 102 are formed, respectively. As an etching gas, SF₆ and C₄F₈ are used. Although the alignment marks 5 are also simultaneously formed by silicon etching, since an opening width thereof is small, the silicon etching rate is lower than that of the first and second through-holes. Next, Cr, a protective film (fluorocarbon film) formed during the Bosch process, and organic contaminations are removed, so that the surfaces of the wafer are cleaned. For the washing, a treatment by O₂ plasma, an etching treatment of Cr, and a washing treatment by a mixed solution of sulfuric acid and a hydrogen peroxide solution are used. Next, as shown in FIG. 1B, after the first and the second conductive substrates 1 and 2 are set in an alignment apparatus so that the surface of the first conductive substrate 1 from which the etching is started is arranged so as to form the outer part of the bonded electrode 4, alignment is performed based on the alignment marks 5 so that the first and the second through-holes communicate with each other. Next, as shown in FIG. 1C, anode bonding is performed. As the bonding conditions, the temperature is set to 220 degrees Celsius and the voltage between the substrates is set to 500 V. When powdered sodium is precipitated on the surface of the conductive substrate by anode bonding, washing is performed using a hydrofluoric acid solution, and sodium is removed without giving any damage on the shape of silicon.

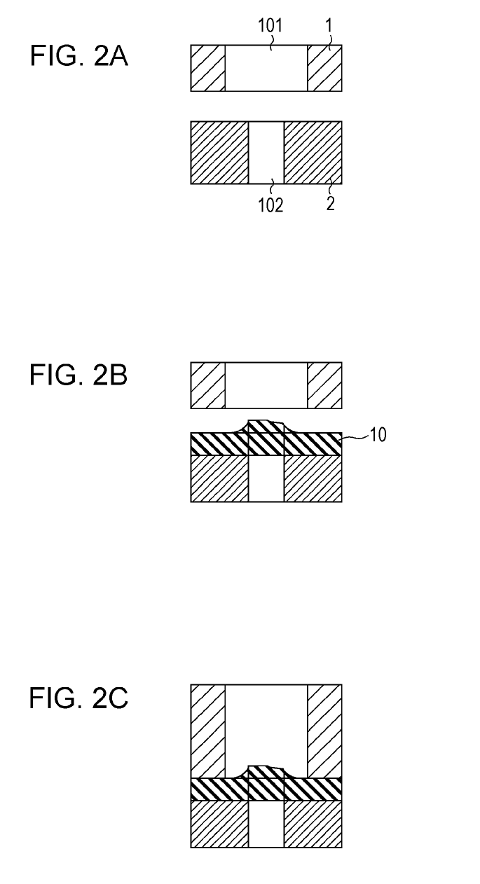

FIGS. 2A to 2C are each an enlarged view in the vicinity of the bonding interface between the substrates in which the through-holes have different diameters.

In FIG. 2A, the first conductive substrate having the first through-hole 101 and the second conductive substrate having the second through-hole 102, the diameter of which is different from that of the first through-hole 101, are prepared.

In FIG. 2B, the conductive substrate with a through-hole having a smaller diameter is thermally oxidized. In this case, a bird beak is generated at the corner of the through-hole, and a projection extended upward from the flat surface of the substrate may be generated in some cases.

In FIG. 2C, when a bird beak 11 is generated, after alignment is performed so that the bird beak 11 is received inside the first through-hole, the bonding is performed.

In addition, after the bonding, the bird beak 11 may be removed by using a hydrofluoric acid solution. In addition, when the alignment mark 5 is formed by etching of silicon, if thermal oxidation is performed, the bird beak 11 may also be generated in the alignment mark 5 in some cases. Therefore, when the surface in which the alignment mark 5 is formed is used as the bonding interface, it is preferable that the bird beak 11 is removed beforehand or a recess is formed in the other substrate to be bonded. As a bonding method, although a method which can obtain electric conduction between the substrates is preferable, when a bonding method, such as fusion bonding, is used in which electric conduction is not obtained since SiO₂ is present at the bonding interface, after the bonding is performed, an additional step of obtaining electric conduction may be performed, if needed. The additional step may be performed in such a way that after a through-hole is provided in one conductive substrate as a conduction hole by dry etching, SiO₂ at the bottom of the conduction hole is removed after the bonding, and a conductive film is then formed by sputtering or the like.

### Example 2

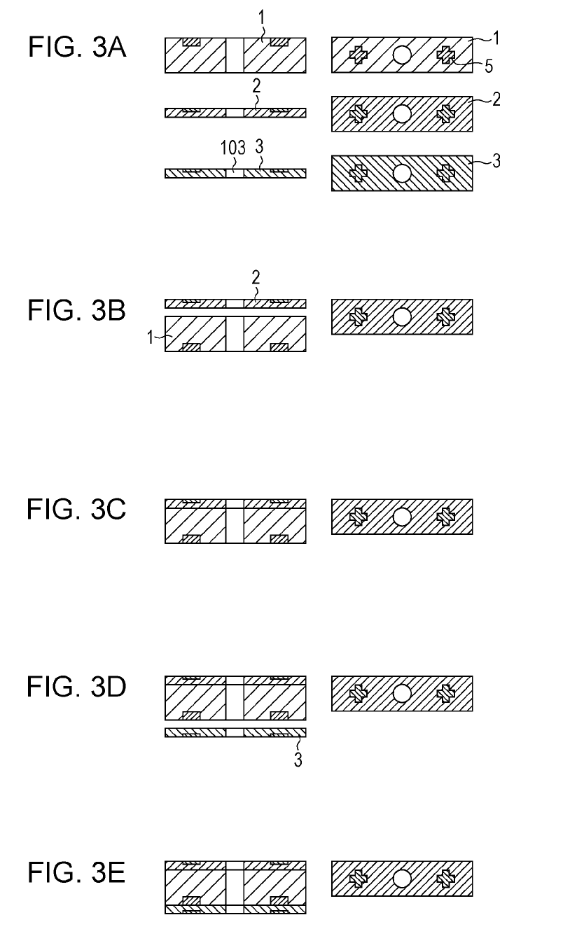

Example 2 will be described with reference to FIGS. 3A to 3E. In this example, the case in which a step of bonding at least three conductive substrates is performed will be described. Since the thickness of one conductive substrate can be decreased by increasing the number of the conductive substrates to be bonded, the cross-sectional pattern accuracy of the through-hole 100 can be improved.

FIG. 3A includes steps of forming a first, a second, and a third through-hole in a first, a second, and a third conductive substrate, respectively.

A method for forming a through-hole is similar to that in Example 1.

FIG. 3B shows a step of aligning the first conductive substrate and the second conductive substrate so that the first through-hole communicates with the second through-hole. In the alignment step and the bonding step, although alignment and bonding of the first, the second, and the third conductive substrates may be simultaneously performed, after the first and the second conductive substrates are bonded to each other, a third conductive substrate 3 may be bonded thereto after the alignment. FIG. 3B shows a step of aligning the first and the second conductive substrates.

FIG. 3C shows a step of bonding the first conductive substrate and the second conductive substrate so that the first through-hole communicates with the second through-hole.

FIG. 3D shows a step of aligning the first conductive substrate, the second conductive substrate, and the third conductive substrate so that the first through-hole, the second through-hole, and the third through-hole communicate with each other. The alignment is performed based on the alignment marks 5 of the second and the third conductive substrates.

FIG. 3E shows a step of bonding the third conductive substrate to a surface of the first conductive substrate opposite to the surface thereof to which the second conductive substrate is bonded. In the case in which at least three conductive substrates are bonded to each other, when the substrates are arranged in each step so that the alignment marks 5 are directed to the outside, and the alignment and the bonding are then performed, the alignment can be easily performed. The order of performing alignment and bonding of the conductive substrates and the arrangement thereof may be changed therebetween, if needed.

The steps will be particularly described. A 4-inch double-sided polished silicon wafer having a thickness of 200 micrometers is prepared as the first conductive substrate 1. Next, two 4-inch double-sided polished silicon wafers each having a thickness of 100 micrometers are prepared as the second conductive substrate 2 and the third conductive substrate 3. A step of forming a Cr mask of each substrate and preceding steps are similar to those in Example 1. Next, the Bosch process is performed on the first conductive substrate 1, so that the first through-hole 101 is formed. The second and the third through-holes are formed by performing ICP-RIE using a mixed gas of SF₆ and CHF₃ on the second conductive substrate 2 and the third conductive substrate 3 (FIG. 3A). Next, washing similar to that in Example 1 is performed. After native oxide films of the conductive substrates are removed by a hydrofluoric acid, bonding surfaces are activated by Ar plasma. Next, as shown in FIG. 3B, the first conductive substrate 1 and the second conductive substrate 2 are aligned to each other based on the alignment marks 5. Next, in FIG. 3C, direct bonding is performed. Next, in FIG. 3D, the bonded electrode 4 formed by bonding the first conductive substrate 1 and the second conductive substrate 2 is aligned to the third conductive substrate 3. Next, in FIG. 3E, bonding of the bonded electrode 4 and the third conductive substrate is performed in a manner similar to that described above. As described above, the bonded electrode and the charged particle beam lens of the present invention can be formed.

### Example 3

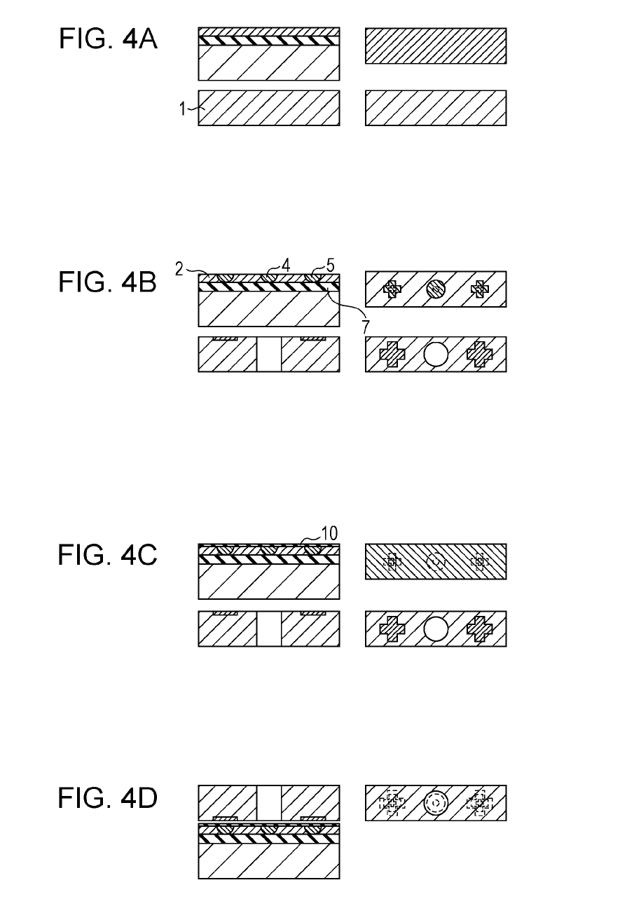

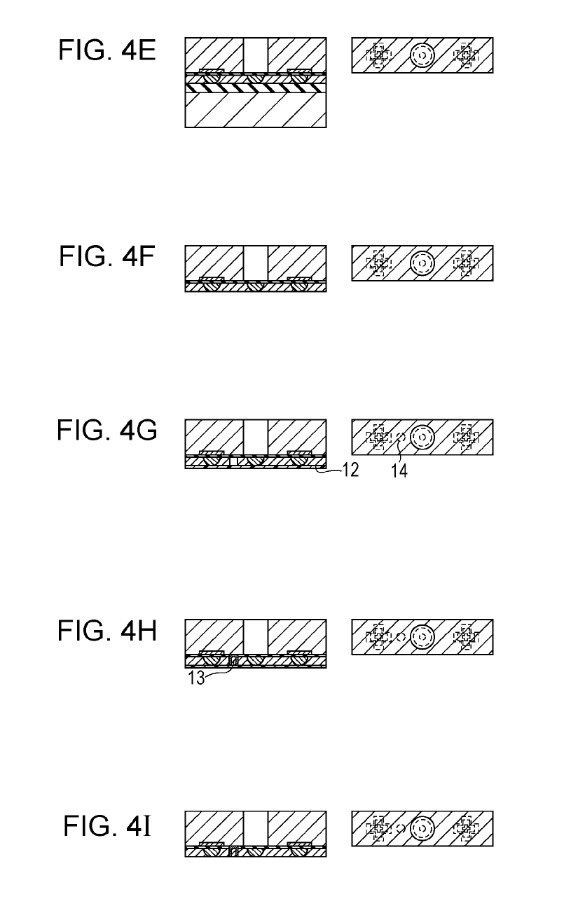

Example 3 will be described with reference to FIGS. 4A to 4I. In this example, a step of forming a conductive substrate from an SOI substrate is included. When a through-hole is formed by a semiconductor process, if the thickness of a substrate is extremely small, the substrate is liable to be bent, and highly accurate machining becomes difficult to perform. Therefore, although highly accurate machining can be performed when all the conductive substrates forming the bonded electrode 4 are each formed from an SOI substrate, depending on required accuracy, an SOI substrate may only be used for some conductive substrate.

In FIGS. 4A to 4I, at least one of the first to third conductive substrates is formed form a device layer of an SOI substrate.

FIGS. 4A to 4I show a process in which the first conductive substrate 1 is formed from a silicon wafer, and the second conductive substrate 2 is formed from an SOI substrate.

FIG. 4A shows a step of preparing an SOI wafer and a silicon wafer. FIG. 4B includes steps of forming the first and the second through-holes in the first and the second conductive substrates, respectively. Patterning is performed on the surface of the device layer 6 of the SOI substrate, and the second through-hole 102 is formed toward a BOX layer 7 from the surface of the device layer 6. The second through-hole 102 may penetrate at least the device layer 6. The device layer 6 is regarded as the second conductive substrate after the handle layer 8 is removed. A patterning method and a method for etching the device layer 6 are similar to those in Examples 1 and 2. Since the BOX layer 7 is formed of SiO₂, notches are liable to be generated on the side wall of the second through-hole 102 in dry etching, and hence an over etching time is preferably minimized

FIG. 4C shows a step of forming the surface of the device layer 6 into a SiO₂ film by thermal oxidation. FIG. 4D shows a step of aligning the first and the second conductive substrates. FIG. 4E shows a step of bonding the first and the second conductive substrates. FIG. 4F shows a step of removing the handle layer 8 and the box layer 7 of the SOI wafer. FIG. 4G shows a step of forming a conduction hole 14 in the second conductive substrate. FIG. 4H shows a step of depositing a conductive film 13 on the surface of the conduction hole 14.

Since a SiO₂ film is present at the bonding interface between the first conductive substrate 1 and the second conductive substrate 2 by fusion bonding, besides the through-hole 100 through which electron beams pass, the conduction hole 14 is also provided. The conduction hole 14 may penetrate one of the first conductive substrate 1 and the second conductive substrate 2 so as to penetrate the SiO₂ film present at the bonding interface. An area other than the conduction hole is protected by using a photoresist, and a conducting film is deposited on the side wall and the bottom of the conduction hole by sputtering or vacuum evaporation, so that the first conductive substrate and the second conductive substrate are electrically connected to each other. In order to form the conductive film 13 as a continuous film, the conductive hole 14 preferably has a tapered side wall rather than a vertical side wall.

FIG. 4I shows a step of removing the photoresist 12 used for the protection when the conductive film 13 is deposited.

The steps of this example will be described in more particular. One 4-inch SOI wafer and one 4-inch silicon wafer are prepared as the substrates. There are prepared the device layer 6 of the SOI wafer having a polished silicon surface, a thickness of 10 micrometers, and a p-type conductivity, a SiO₂ film 10 of the BOX layer 7 having a thickness of 1 micrometer, and silicon of the handle layer 8 having a thickness of 514 micrometers. The thickness of the silicon wafer is 200 micrometers. The silicon wafer is used as the first conductive substrate 1, and the device layer 6 of the SOI wafer is used as the second conductive substrate 2. A step of forming the first through-hole 101 in the first conductive substrate 1 is performed by the Bosch process as in the case of Examples 1 and 2. The diameter of the through-hole of the first conductive substrate 1 is set to 40 micrometers, and that of the second conductive substrate 2 is set to 30 micrometers. A step of forming the alignment marks 5 and the Cr pattern on the surface of the first conductive substrate 1 is the same as that of the formation on the surface of the silicon wafer in Examples 1 and 2. Next, the second through-hole 102 is formed from the surface of the device layer 6 to the BOX layer 7. For the above step, isotropic dry etching is performed using SF₆. The same washing step as that in Examples 1 and 2 is performed after each through-hole is formed.

The surface of the first conductive substrate 1 is thermally oxidized to form a SiO₂ film 10 having a thickness of 1,000 angstroms. The surface in which the alignment marks 5 are formed is used as a bonding interface side, and the first conductive substrate 1 and the second conductive substrate 2 are arranged. Alignment is performed using infrared light so that the first and the second through-holes communicate with each other. The arrangement is performed so that the bird beak 11 generated when the SOI wafer is thermally oxidized is received in the first through-hole 101, and the bonding is then performed. Fusion bonding is used for the bonding, and this bonding is performed at a bonding temperature of 65 degrees Celsius, a load of 500 N, and an annealing temperature of 1,050 degrees Celsius. Subsequently, thermal oxidation is performed so that a surface layer of the through-hole 100 of the bonded electrode 4 having a thickness of 1,000 angstroms is thermally oxidized. Next, approximately 450 micrometers of the handle layer 8 is removed by grinding. The remaining handle layer 8 is removed by a TMAH solution until the BOX layer 7 is exposed. Since the surface of the through-hole 100 is protected by the SiO₂ film 10, the BOX layer 7 may be fractured by a stress. Etching is performed by a hydrofluoric acid after the removal of the handle layer 8, so that the SiO₂ film and the BOX layer 7 on the surface of the bonded electrode 4 are removed. The charged particle beam lens of the present invention is formed through the steps as described above.

### Example 4

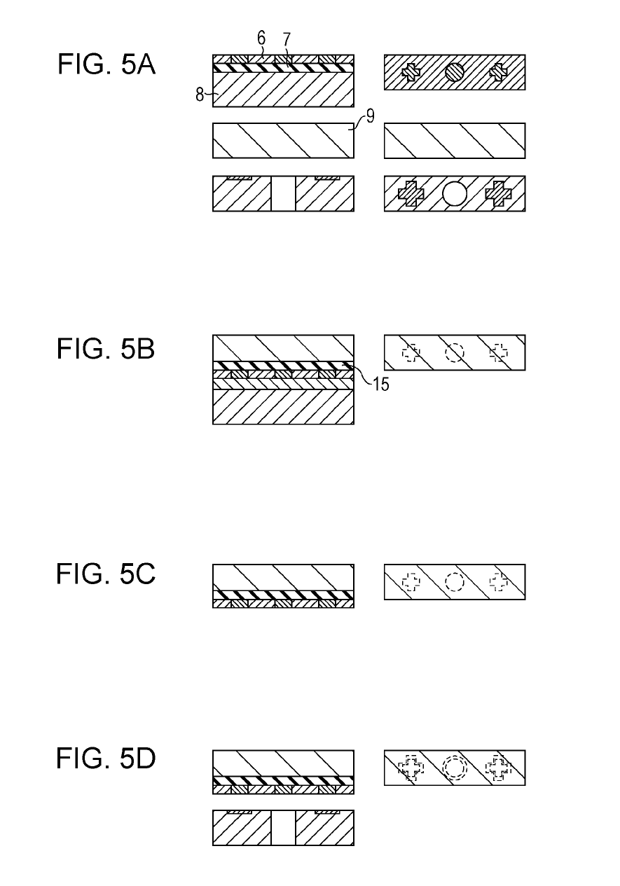

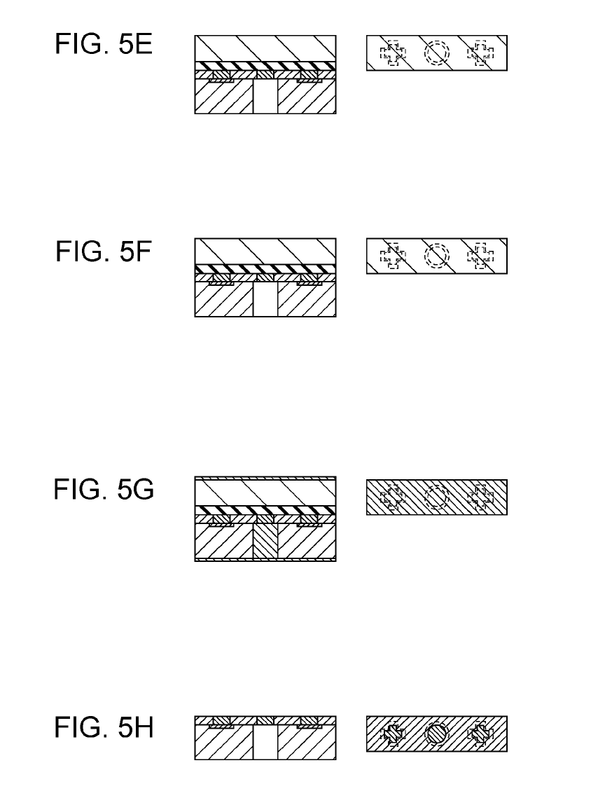

Example 4 will be described with reference to FIGS. 5A to 5H. The present invention includes, after the device layer 6, which functions as the substrate, of the SOI wafer is transferred to a support substrate 9, a step of forming the device layer 6 into the second conductive substrate 2. In the through-hole formation, the pattern transfer accuracy is gradually degraded from the etching start side to the etching finish side. The reason for this is that as the etching progresses, the shape of an inner wall of an etching hole to function as the through-hole is nonuniformly changed. In addition, influence of the machining accuracy of the electron beam lens on the aberration is larger at the outer part of the electrode. Therefore, when the device layer 6 is once transferred to the support substrate and is then bonded to the first conductive substrate 1, the aberration can be decreased. When the device layer 6 is a single layer having a certain thickness so as to be handled, after the second through-hole 102 is formed in the device layer 6, the BOX layer 7 and the handle layer 8 are removed without performing the transfer step, and after being reversed, the device layer 6 may be bonded to the first conductive substrate. The steps are shown in FIGS. 5A to 5H.

FIG. 5A includes steps of forming the first and the second through-holes in the first conductive substrate 1 and the device layer 6 of the SOI wafer, respectively, and a step of preparing the support substrate 9. As in Examples 1, 2, and 3, the SOI wafer is washed after the through-hole formation to remove etching residues and the mask material, so that the device layer 6 becomes clean silicon.

FIG. 5B shows a step of bonding the device layer 6 to the support substrate 9 with a separating layer 15 provided therebetween.

FIG. 5C shows a step of removing the handle layer 8 and the BOX layer 7 of the SOI wafer. As the separating layer 15, any layer may be used as long as the device layer 6 can be separated without any damage done thereto, and when fusion bonding is used in a subsequent bonding step, as the separating layer, a SiO₂ film can be used. When anode bonding or direct bonding is used, an adhesion sheet or a wax material may be used as the separating layer. A material of the support substrate 9 is preferably a material which can be bonded to the device layer 6 and which can peel off the device layer 6. In addition, since the support substrate 9 must be bonded to the device layer 6 without causing any distortion thereof, the flatness is required for the support substrate 9. Accordingly, as the support substrate 9, a SiO₂ substrate is used, or a flat substrate having a wax on its surface or an adhesive tape is preferably used.

FIG. 5D shows a step of aligning the first conductive substrate 1 and the device layer 6.

FIG. 5E shows a step of bonding the first conductive substrate 1 and the device layer 6 adhered to the support substrate 9.

FIG. 5H shows a step of removing the support substrate 9 and the separating layer 15.

The support substrate 9 may be mechanically peeled off or may be removed using an etching solution by which silicon is not etched so as not to damage the device layer 6 which is formed into the second conductive substrate 2.

Furthermore, the steps of this example will be particularly described. By a procedure similar to that in Example 3, the second conductive substrate 2, which is the device layer 6 of the SOI wafer in which the second through-hole 102 is formed, and the first conductive substrate 1, which is the silicon substrate in which the first through-hole 101 is formed, are prepared. After Cr on the first conductive substrate 1 is removed, and contaminations are washed out, thermal oxidation is performed. Since the bird beak 11 is generated on the surface of the substrate around the first through-hole 101, the photoresist 12 is applied to the device layer 6 and is patterned so that a portion of the bird beak 11 is exposed, and dry etching using CF₄ is performed, so that the bird beak 11 is removed. Next, the device layer 6 and the support substrate 9 are bonded to each other. As the support substrate 9, a mirror-polished silicon substrate is used. After a native oxide film on the surface of the support substrate 9 is removed by a hydrofluoric acid, fusion bonding between the support substrate 9 and the device layer 6 is performed, and the BOX layer 7 and the handle layer 8 are removed. The bonding and the removal of the BOX layer 7 and the handle layer 8 are similar to those in Example 3. The device layer 6 bonded to the support substrate 9 is bonded to the first conductive substrate 1 by direct bonding, and the support substrate 9 is removed by a method similar to that of removing the handle layer 8 of the SOI wafer in Example 3. Through the steps as described above, the charged particle beam lens of the present invention is formed.

### Example 5

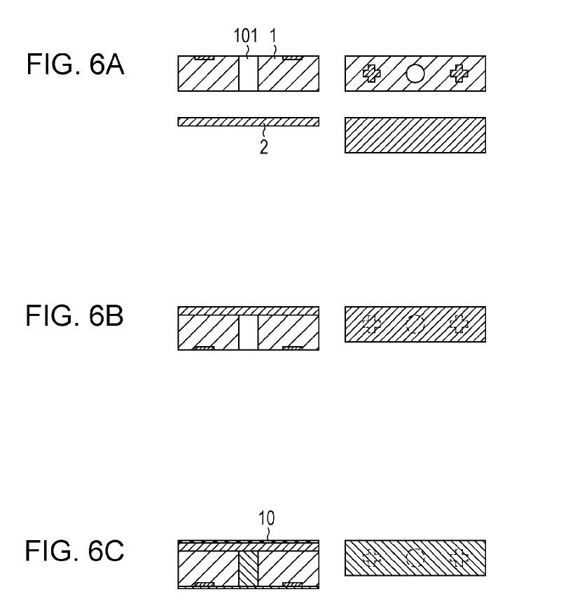

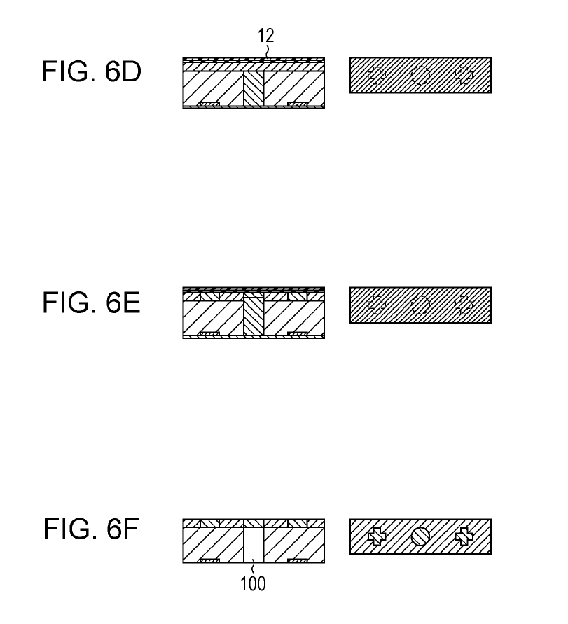

Example 5 will be described with reference to FIGS. 6A to 6F. This example includes, after the first through-hole 101 is formed in the first conductive substrate 1, a step of bonding the first conductive substrate 1 and the second conductive substrate 2 in which the through-hole is not yet formed and a step of forming the second through-hole 102 in the second conductive substrate 2 at a position at which alignment is performed with respect to the first through-hole 101. Although the conductive substrates in which the through-holes are formed are bonded to each other in Examples 1 to 4, in Example 5, after the bonding step, the second through-hole 102 is formed in the second conductive substrate 2. Thereby, the number of voids generated at the time of bonding can be reduced. In the bonding, when the substrate is cleaner and has a higher flatness, voids are more unlikely to be generated by bonding. Since machining of the second conductive substrate 2 is performed after the bonding, the cleanness and the flatness of the second conductive substrate 2 can be easily ensured. FIGS. 6A to 6F show the manufacturing steps.

FIG. 6A includes a step of forming the first through-hole 101 in the first conductive substrate 1 and a step of preparing the second conductive substrate 2.

FIG. 6B shows a step of bonding the first conductive substrate 1 and the second conductive substrate 2. The first conductive substrate 1 in which the first through-hole 101 is formed and the second conductive substrate 2 in which the through-hole is not yet formed are bonded to form the bonded electrode 4.

FIG. 6C shows a step of thermally oxidizing the bonded electrode 4. This step is a step to protect the first through-hole 101 when the second through-hole 102 is formed. Since a material having a high selection ratio to silicon in dry etching is preferable, a SiO₂ film and a SiN film are preferable. After the second through-hole 102 is formed in the second conductive substrate, the film formed in this step is preferably removed.

FIG. 6D shows a step of performing patterning on the second conductive substrate at the position at which alignment is performed with respect to the first through-hole.

FIG. 6E shows a step of forming the second through-hole 102 from a second conductive substrate 2 side so as to communicate with the first through-hole 101.

FIG. 6F shows a step of removing a photoresist, a hard mask, and a SiO₂ film. The patterning, the alignment, and the method for forming the through-hole 100 are similar to those in Examples 1 to 4.

Furthermore, the steps of this example will be particularly described. Two 4-inch double-sided polished silicon wafers each having a thickness of 100 micrometers are prepared. One wafer is used as the first conductive substrate 1, and the first through-hole 101 is formed therein. The other wafer is used as the second conductive substrate 2 in which a through-hole is not yet formed. Native oxide films on the surfaces of the first conductive substrate 1 and the second conductive substrate 2 are removed, and direct bonding is performed therebetween to form the bonded electrode 4. The through-hole formation and the direct bonding are performed in a manner similar to those in Examples 1, 2, and 3. Thermal oxidation is performed after the bonding so that the surface of the bonded electrode 4 is formed into a SiO₂ film. Pattern formation of the photoresist 12 is performed on the SiO₂ film 10 of the bonded electrode 4 at a first conductive substrate 1 side, and the SiO₂ film 10 is patterned by dry etching using CHF₃. The patterning is performed based on the alignment marks 5 of the first conductive substrate 1. By using the pattern of this SiO₂ film 10 as a hard mask, etching is performed by the Bosch method from the conductive substrate side toward the bonding interface. Even if the SiO₂ film 10 at the bonding interface is fractured by a stress, since the side wall of the through-hole 100 of the first conductive substrate 1 is formed into a SiO₂ film, any problems may not occur since damage is not likely to be done thereto. After the film deposited by the Bosch process is removed by O₂ plasma, the SiO₂ film 10 is removed by a hydrofluoric acid. Through the steps as described above, the charged particle beam lens of the present invention is formed.

### Example 6

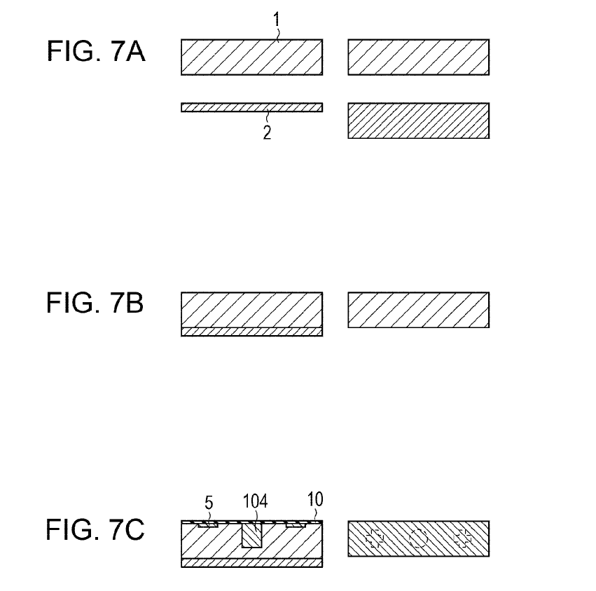

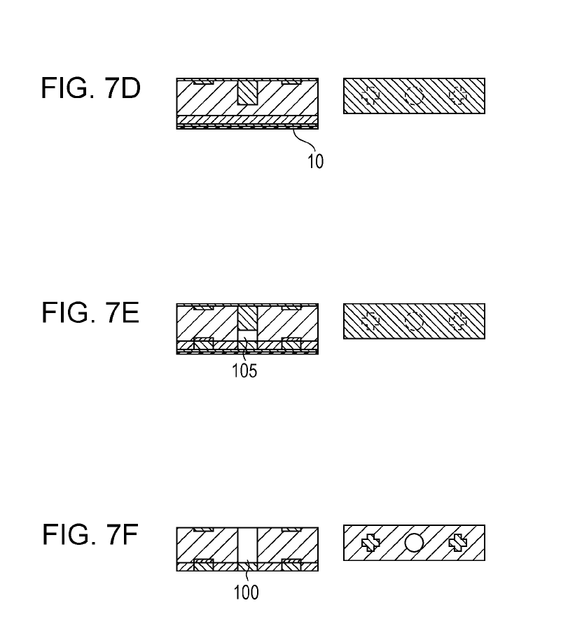

Example 6 will be described with reference to FIGS. 7A to 7F. In this example, the case will be described in which a step of forming the first through-hole 101 of the bonded electrode 4 from the first conductive substrate 1 side and a step of forming the second through-hole 102 of the bonded electrode 4 from the second conductive substrate 2 side so as to communicate with the first through-hole 101 are included.

Since the first conductive substrate 1 and the second conductive substrate 2 are bonded to each other after each being processed by a small number of steps, voids formed in the bonding are not likely to be generated as compared to those in Example 5. As for the formation of the through-hole 100, compared to the case in which the through-hole 100 is formed in the two substrate at a time from one substrate side, when the first and the second through-hole are formed in the respective substrates from two outer sides and are aligned so as to communicate with each other at the bonding interface for the formation the through-hole 100, the cross-sectional machining accuracy of the through-hole 100 is increased. In addition, the SiO₂ film 10 may be formed at the interface between the first conductive substrate 1 and the second conductive substrate 2 before bonding so as to function as a stop layer when the second through-hole 102 is formed. The manufacturing steps are shown in FIGS. 7A to 7F. The formation of the through-hole, the patterning, and the bonding method are similar to those in Examples 1 to 5. Machining of the conduction hole may be similar to that in Example 5.

FIG. 7A shows a step of preparing each conductive substrate.

FIG. 7B shows a step of bonding the conductive substrates.

FIG. 7C shows a step of forming a first hole 104 in the bonded electrodes 4 from the first conductive substrate 1 side toward the second conductive substrate 2 side. In this step, the bottom of the first hole 104 may be at a shallow position or a deep position as compared to that of the bonding interface. When the depth of the first hole 104 is approximately a half of the total thickness of the bonded electrode 4, the cross-sectional machining accuracy of the first hole 104 for communication can be easily maintained.

FIG. 7E shows a step of forming a second hole 105, which is to communicate with the first hole 104, in the bonded electrode 4 from the second conductive substrate 2 side. The order of performing the step of forming a first hole, the step of forming a second hole, the step of enabling the first hole to communicate with the second hole, and the step of bonding the first conductive substrate and the second conductive substrate may be changed, if needed (the order is not particularly limited). As one example, a hole forming step is performed at a position aligned to the first hole 104 from the second conductive substrate 2 side to enable the second hole 105 to communicate with the first hole 104 for the formation of the through-hole 100, so that the bonded electrode 4 is formed.

FIG. 7F shows a washing step. A photoresist, a hard mask, SiO₂, and a fluorocarbon film on the silicon surface are removed. When the side surface of the first through-hole 101 is formed into a SiO₂ film, the shape thereof can be easily maintained when the second through-hole 102 is formed. When a SiO₂ film is provided at the interface, besides the through-hole 100 for electron beams, machining is performed to electrically connect the first conductive substrate 1 and the second conductive substrate 2.

Furthermore, the steps of this example will be particularly described. Two 4-inch double-sided polished wafers each having a thickness of 100 micrometers are prepared as the first conductive substrate 1 and the second conductive substrate 2. The above two substrates in each of which the through-hole 100 for electron beam passage is not yet provided are directly bonded to each other under conditions similar to those in Example 2. Next, the surfaces of the substrate are each thermally oxidized to form a SiO₂ film, and the SiO₂ film 10 at the first conductive substrate 1 side is patterned using the photoresist 12 and dry etching. Next, silicon is etched from the first conductive substrate 1 side to the bonding interface by the Bosch process. Then, after the fluorocarbon film formed by the Bosch process is removed by O₂ plasma and a sulfuric acid-hydrogen peroxide solution, thermal oxidation is performed. Next, patterning at the second conductive substrate 2 side is performed. Patterning of the photoresist 12 is performed at a position at which the alignment is performed to the alignment marks 5 of the first conductive substrate 1 using a double side aligner. Since the thickness of the SiO₂ film is larger than that at the time of patterning of the first conductive substrate 1 side, when the second conductive substrate 2 is etched, the time of dry etching is adjusted so that silicon is exposed. Next, from the second conductive substrate 2 side to the SiO₂ film 10 at the bonding interface, silicon is etched by the Bosch process. Even if the SiO₂ film 10 at the interface is fractured, since the surface of the hole formed in the first conductive substrate 1 is formed into a SiO₂ film, damage to be done thereto is small. The SiO₂ film 10 is removed after the fluorocarbon film is removed. The charged particle beam lens of the present invention is formed through the steps as described above.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-056810, filed Mar. 15, 2011, which is hereby incorporated by reference herein in its entirety.

1. A method for manufacturing a charged particle beam lens having a bonded electrode obtained by bonding at least a first conductive substrate having a first through-hole and a second conductive substrate having a second through-hole, the method comprising:
forming the first through-hole in the first conductive substrate;
forming the second through-hole in the second conductive substrate; and
bonding the first conductive substrate and the second conductive substrate so that the first through-hole and the second through-hole communicate with each other.

2. The method for manufacturing a charged particle beam lens according to claim 1,
further comprising: boding a third conductive substrate having a third through-hole to the second conductive substrate bonded to the first conductive substrate so that the first through-hole, the second through-hole, and the third through-hole communicate with each other.

3. The method for manufacturing a charged particle beam lens according claim 1,
wherein at least one of the conductive substrates includes a device layer of an SOI substrate.

4. The method for manufacturing a charged particle beam lens according to claim 3,
wherein the device layer of the SOI substrate has a through-hole,
further comprising: after the device layer and at least one of the conductive substrates are bonded to each other, removing a handle layer and a BOX layer of the SOI substrate.

5. The method for manufacturing a charged particle beam lens according to claim 3,
wherein the device layer of the SOI substrate has a through-hole,
further comprising:
bonding a support substrate to the device layer with a separating layer provided therebetween;
removing a handle layer and a BOX layer of the SOI substrates; and after at least one of the conductive substrates and a surface of the device layer on which the box layer is formed as a bonding surface are bonded to each other, separating the support substrate by the separating layer.

6. A method for manufacturing a charged particle beam lens having a bonded electrode obtained by bonding at least a second conductive substrate and a first conductive substrate having a first through-hole, the method comprising:
forming the first through-hole in the first conductive substrate;
bonding the first conductive substrate and the second conductive substrate; and
forming a second through-hole in the second conductive substrate so as to communicate with the first through-hole.

7. A method for manufacturing a charged particle beam lens having a bonded electrode obtained by bonding at least a first conductive substrate and a second conductive substrate, the method comprising:
forming a first through-hole in the bonded electrode from a side of the first conductive substrate; and
forming a second through-hole in the bonded electrode from a side of the second conductive substrate so as to communicate with the first through-hole.

8. The method for manufacturing a charged particle beam lens according to claim 1,
wherein the diameter of the first through-hole is different from the diameter of the second through-hole.

9. A method for manufacturing a charged particle beam lens having a bonded electrode obtained by bonding at least a first conductive substrate having a first hole and a second conductive substrate having a second hole, the method comprising:
forming the first hole in the first conductive substrate; forming the second hole in the second conductive substrate; bonding the first conductive substrate and the second conductive substrate; and
enabling the first hole to communicate with the second hole.
